(19) United States
(12) Patent Application Publication
(10) Pub. No.: US 2010/0195069 A1
(43) Pub. Date: Aug. 5, 2010

(54) EXPOSURE METHOD AND EXPOSURE SYSTEM

(76) Inventor: Kazuya FUKUHARA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/696,111

(22) Filed: Jan. 29, 2010

(30) Foreign Application Priority Data
Feb. 3, 2009 (JP) 2009-22398

(51) Int. Cl. G03B 27/68; G03F 7/20

(52) U.S. Cl. 355/52; 430/30

(57) ABSTRACT

An exposure method has acquiring first OPE (Optical Proximity Effect) error corresponding to a first and second transcriptional pattern portions formed by transcribing a first and second pattern portions of a mask pattern onto a substrate with an exposure apparatus, computing a first correction amount of an exposure condition, the first correction amount reducing the first OPE error, computing a best focus difference between the first transcriptional pattern portion and the second transcriptional pattern portion transcribed with the exposure apparatus to which the first correction amount is imparted, computing a second correction amount of a projection optical system of the exposure apparatus, the second correction amount reducing the best focus difference, acquiring second OPE error corresponding to the first and second transcriptional pattern portions transcribed with the exposure apparatus to which the first and second correction amounts are imparted, and performing exposure processing with the exposure apparatus using a mask comprising the mask pattern, the first correction amount and the second correction amount being imparted to the exposure apparatus, when the second OPE error is included in a predetermined range.

### CROSS REFERENCE TO RELATED APPLICATIONS

This application is based upon and claims benefit of priority from the Japanese Patent Application No. 2009-22398, filed on Feb. 3, 2009, the entire contents of which are incorporated herein by reference.

### BACKGROUND OF THE INVENTION

The present invention relates to an exposure method and an exposure system.

With the progress of microfabrication for an LSI circuit pattern, a so-called. Optical Proximity Effect (OPE) becomes troublesome. In OPE, a dimensional fluctuation or a shape change is generated between a pattern of an exposure mask and a pattern obtained on a wafer according to density and periodicity of the pattern. Optical Proximity Correction (OPC), in which the mask pattern is corrected in previous consideration of an influence of OPE, is performed as a countermeasure against the OPE.

In the LSI production, because of concurrent processing of a large amount of semiconductor wafers, exposure processing is performed with plural exposure apparatuses of the same model. In the plural exposure apparatuses, even if the exposure apparatuses are the same model, actually the influence of OPE depends on an individual difference of each apparatus. Therefore, there is generated a problem in that sometimes a desired pattern is not obtained, when the exposure processing is performed with a second exposure apparatus using a mask to which OPC is performed according to a first exposure apparatus.

In order to solve the problem, for example, Japanese Patent Application Laid-Open No. 2006-229042 discloses a method in which a coherence factor of one of a first exposure apparatus and a second exposure apparatus is adjusted such that a difference of the optical proximity effect becomes the minimum when the pattern is transcribed to a material using the same mask with each of the first exposure apparatus and the second exposure apparatus.

For example, Japanese Patent Application Laid-Open No. 2002-329645 discloses a method, in which information on spatial frequency dependence of a lithography transfer function is obtained for each of two exposure apparatuses and machine setting such as an illumination shape is changed in one of the exposure apparatuses such that a difference of the spatial frequency dependence between the exposure apparatuses becomes the minimum.

These methods reduce the necessity to prepare the mask to which different OPC is performed in each exposure apparatus.

However, recently it is found that an influence of spherical aberration cannot be considered under exposure conditions that a minimum half pitch becomes about 45 nm or less with an immersion exposure apparatus in which Numerical Aperture (NA) of a projection lens exceeds 1.2. The spherical aberration includes aberration that is independent of a polarization state of exposure light and aberration (polarization aberration) that depends on the polarization state. Particularly, because the polarization aberration is caused by lens birefringence, it is difficult to adjust the polarization aberration after the lens is produced. A deviation of best focus is generated according to a pattern pitch or a pattern shape by an influence of the spherical aberration. On the other hand, that a Depth Of Focus (DOF) that can be used to form the pattern decreases with increasing NA is well known as a Rayleigh's equation, and sophisticated focus management is required under such the condition that NA exceeds 1.2 (for example, see Japanese Patent Application Laid-Open No. 2005-197690).

That is, under the conditions that the minimum half pitch becomes about 45 nm or less in ArF immersion exposure, an inter-pattern best focus difference is generated between at least two kinds of the patterns having narrow depth of focus in the same mask by the influence of the spherical aberration, and dimensional accuracy becomes incompatible between the patterns, which causes a problem in that a yield is degraded in semiconductor device production. Particularly, because the aberration depends on the exposure apparatus, even if the difference of the optical proximity effect is suppressed among the exposure apparatuses, and the dimensional accuracy fluctuates among the exposure apparatuses, which causes a problem in that the yield of the semiconductor device is not stabilized.

### SUMMARY OF THE INVENTION

According to one aspect of the present invention, there is provided an exposure method comprising:

acquiring first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus;

computing a first OPE error based on the first OPE information;

computing a first correction amount of an exposure condition, the first correction amount reducing the first OPE error;

computing a best focus difference between the first transcriptional pattern portion and the second transcriptional pattern portion, the first transcriptional pattern portion and the second transcriptional pattern portion being transcribed with the exposure apparatus to which the first correction amount is imparted;

computing a second correction amount of a projection optical system of the exposure apparatus, the second correction amount reducing the best focus difference;

acquiring second OPE information corresponding to the first transcriptional pattern portion and the second transcriptional pattern portion, the first transcriptional pattern portion and the second transcriptional pattern portion being transcribed with the exposure apparatus to which the first correction amount and the second correction amount are imparted;

computing a second OPE error based on the second OPE information; and

performing exposure processing with the exposure apparatus using a mask comprising the mask pattern, the first correction amount and the second correction amount being imparted to the exposure apparatus, when the second OPE error is included in a predetermined range.

According to one aspect of the present invention, there is provided an exposure method comprising:

acquiring first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus;

computing a first best focus difference between the first transcriptional pattern portion and the second transcriptional pattern portion with the exposure apparatus;

computing a first correction amount of a projection optical system of the exposure apparatus, the first correction amount reducing the first best focus difference;

acquiring second OPE information corresponding to the first transcriptional pattern portion and the second transcriptional pattern portion, the first transcriptional pattern portion and the second transcriptional pattern portion being transcribed with the exposure apparatus to which the first correction amount are imparted;

computing an OPE error based on the second OPE information;

computing a second correction amount of an exposure condition, the second correction amount reducing the OPE error;

computing a second best focus difference between the first transcriptional pattern portion and the second transcriptional pattern portion, the first transcriptional pattern portion and the second transcriptional pattern portion being transcribed with the exposure apparatus to which the first correction amount and the second correction amount are imparted; and

performing exposure processing with the exposure apparatus using a mask comprising the mask pattern, the first correction amount and the second correction amount being imparted to the exposure apparatus, when the second best focus difference is included in a predetermined range.

According to one aspect of the present invention, there is provided an exposure system comprising:

an exposure apparatus which comprises a projection optical system;

a computing unit which
acquires first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus,
computes a first OPE error based on the first OPE information,
computes a first correction amount of an exposure condition, the first correction amount reducing the first OPE error,
computes a best focus difference between the first transcriptional pattern portion and the second transcriptional pattern portion, the first transcriptional pattern portion and the second transcriptional pattern portion being transcribed with the exposure apparatus to which the first correction amount is imparted,
computes a second correction amount of a projection optical system of the exposure apparatus, the second correction amount reducing the best focus difference,
acquires second OPE information corresponding to the first transcriptional pattern portion and the second transcriptional pattern portion, the first transcriptional pattern portion and the second transcriptional pattern portion being transcribed with the exposure apparatus to which the first correction amount and the second correction amount are imparted, and computes a second OPE error based on the second OPE information; and

a management unit that imparts the first correction amount and the second correction amount to the exposure apparatus when the second OPE error is included in a predetermined range.

### BRIEF DESCRIPTION OF THE DRAWINGS

FIG. 1 is a schematic diagram of an exposure system according to a first embodiment of the invention;

FIG. 2 is a graph illustrating a relationship between a defocus amount and a resist dimension of a resist pattern formed by an exposure processing;

FIG. 3 is a flowchart illustrating an exposure method according to the first embodiment;

FIG. 4 is a graph illustrating an example of a focus management range and a dimension variation range;

FIG. 5 is a graph illustrating an example of a fluctuation of a best focus position according to lens aberration adjustment;

FIG. 6 is a graph illustrating an example of the focus management range and the dimension variation range after the lens aberration adjustment;

FIG. 7 illustrates another example of a transcriptional pattern;

FIG. 8 is a graph illustrating a relationship between the defocus amount and a long-diameter dimension and a short-diameter dimension of the resist pattern formed by the exposure processing;

FIG. 9 is a flowchart illustrating an exposure method according to a second embodiment of the invention;

FIG. 10 illustrates an example of a pattern laid out in a mask;

FIG. 11 is a graph illustrating an example of a relationship between a focus offset and a resist dimension of a resist pattern;

FIG. 12 is a graph illustrating an example of the relationship between the focus offset and the resist dimension of the resist pattern when projection lens aberration is corrected;

FIG. 13 is a graph illustrating an example of the relationship between the focus offset and the resist dimension of the resist pattern when illumination sigma value is corrected;

FIG. 14 is a schematic diagram of an exposure system according to a third embodiment of the invention; and

FIG. 15 is a flowchart illustrating an exposure method according to the third embodiment.

### DETAILED DESCRIPTION OF THE INVENTION

Hereafter, exemplary embodiments of the invention will be described more specifically with reference to the drawings.

### First Embodiment

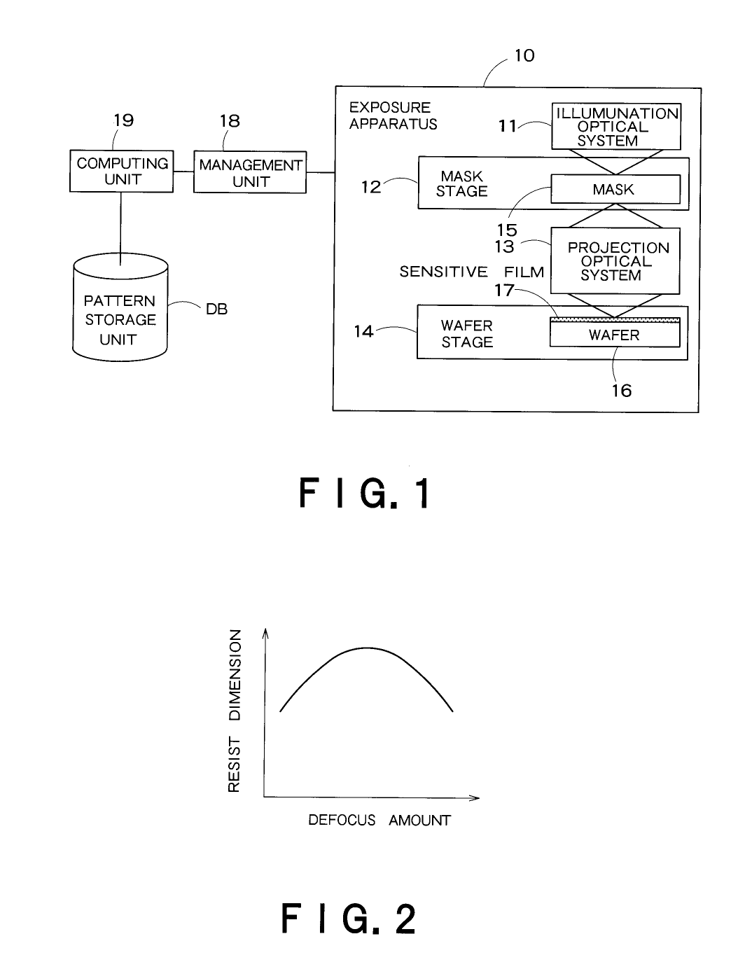

FIG. 1 is a schematic diagram of an exposure system according to a first embodiment of the invention. The exposure system includes an exposure apparatus 10, a management unit 18, a computing unit 19, and a pattern storage unit DB. The exposure apparatus 10 includes an illumination optical system 11, a mask stage 12, a projection optical system (lens) 13, and a wafer stage 14.

A mask 15 having a pattern surface is placed on the mask stage 12, and a pattern to be exposed is formed in the pattern surface. For example, a line and space pattern (L/S pattern) is formed in the mask 15. The L/S pattern includes at least two kinds of patterns whose shapes are different from each other such that one of the patterns has a narrow line width and a narrow space width while the other pattern has a narrow line width and a wide space width.

A wafer (substrate) 16, in which one or plural layers including a sensitive film 17 are laminated, is placed on the wafer stage 14.

Light emitted from the illumination optical system 11 passes through the mask 15 and the lens 13, and an image is formed near an upper surface of the substrate 16, thereby transcribing an image of a mask pattern.

The computing unit 19 computes a dimensional error between the pattern in the mask 15 and a transcriptional pattern target value estimated from a current state of the exposure apparatus 10. Therefore, the computing unit 19 obtains a correction amount of setting of the exposure apparatus 10 in order to reduce the dimensional error. The computing unit 19 can also obtain the correction amount by measuring the dimensional error from the transcriptional pattern target value determined by an exposure experiment.

As used herein, the dimensional error means an error from each transcriptional pattern target value when the exposure amount is determined by a well-known method. For example, one kind of transcriptional pattern is selected as a reference pattern from at least two kinds of transcriptional patterns, and the exposure amount is determined such that the reference pattern becomes a target dimension. At this point, the dimensional error expresses a dimensional behavior of the other pattern, and the dimensional error includes the error caused by the Optical Proximity Effect (OPE). Hereinafter, the dimensional behavior depending on the kind of the pattern is referred to as OPE information, and the error from the target dimension depending on the kind of the pattern is referred to as OPE error. The setting of the exposure apparatus 10 is described later.

The computing unit 19 computes a best focus position corresponding to each of at least the two kinds of patterns formed in the mask 15, and the computing unit 19 computes the correction amount of the setting of the exposure apparatus 10 in order to reduce the best focus difference. The setting of the exposure apparatus 10 is described below.

Attention is focused on a certain pattern, and the exposure is performed when a distance (defocus amount) between the substrate 16 and the lens 13 is changed while an exposure amount is fixed. At this point, the best focus means a defocus amount state in which a minor change in resist dimension to a minor change in defocus becomes zero. Generally, a relationship between the defocus amount and the resist dimension becomes a quadratic curve as illustrated in FIG. 2, and the best focus condition is obtained as the defocus amount that imparts an extreme value of the quadratic curve.

The management unit 18 moves the mask stage 12 and the wafer stage 14, and management unit 18 applies the setting correction amount computed by the computing unit 19 to the exposure apparatus 10.

The information on the pattern formed in the mask 15 and target dimension are stored in the pattern storage unit DB.

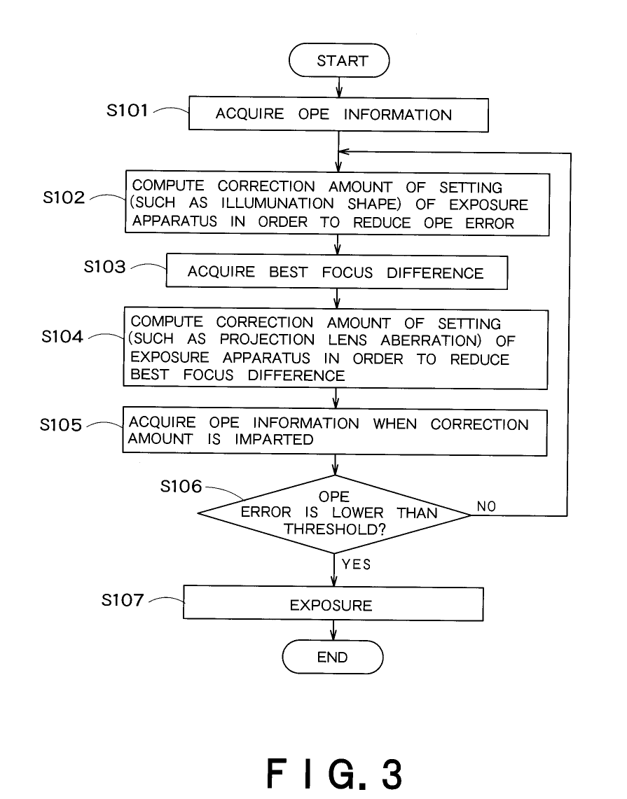

An exposure method in which the exposure system is used will be described with reference to a flowchart of FIG. 3.

(Step S101) The computing unit 19 obtains the OPE information when the transcriptional pattern formed in the mask is collectively transcribed onto the substrate 16 under predetermined exposure conditions.

(Step S102) The computing unit 19 computes the correction amount of the setting of the exposure apparatus 10 such that the OPE error (deviation from the target value) is reduced based on the OPE information obtained in Step S101. Examples of the setting of the exposure apparatus 10, which obtains the correction amount, include an illumination shape (illumination sigma value or luminance distribution) in the illumination optical system 11, NA of the projection optical system 13, a scan surface inclined amount of the wafer stage or mask stage, a spectral shape of a wavelength of the exposure light, and a polarization degree of the exposure light.

The patter transcription is performed to the substrate 16 while the setting of the exposure apparatus 10 is actually changed, and the correction amount may be obtained by measuring the resist dimension.

(Step S103) The computing unit 19 performs an exposure simulation under the exposure conditions that impart the correction amount computed in Step S102, and the computing unit 19 computes the best focus position of each of the two patterns to obtain the best focus difference. In computing the best focus position, a simulation computation is performed in order to obtain an intensity distribution of the light whose image is formed by the projection optical system.

(Step S104) The computing unit 19 computes the correction amount of the setting of the exposure apparatus 10 such that the best focus difference obtained in Step S103 is reduced. For example, the setting of the exposure apparatus 10, which obtains the correction amount, is projection lens aberration.

(Step S105) The computing unit 19 obtains the OPE information under the exposure conditions that impart the correction amounts computed in Steps S102 and S104, when the transcriptional pattern formed in the mask 15 is collectively transcribed onto the substrate 16.

(Step S106) A determination whether the OPE error is lower than a predetermined threshold (whether the OPE error falls within an allowable range) is made based on the OPE information obtained in Step S105. The procedure goes to Step S107 when the OPE error is lower than a predetermined threshold. In Step S105, the OPE error is possibly not lower than the threshold, because the correction amount such as the projection lens aberration is imparted in order to reduce the best focus difference computed in Step S104 after the correction amount such as the illumination shape is imparted in order to reduce the OPE error computed in Step S102. The procedure returns to Step S102 when the OPE error is not lower than a predetermined threshold.

The conditions such as the projection lens aberration differ by the correction amount imparted in Step S105. Therefore, when the procedure goes from Step S101 to Step S102, the correction amount computed in Step S102 differs from the correction amount that is computed in Step S102 when the procedure returns from Step S106 to Step S102.

The pieces of processing in Steps S102 to S106 are repeated until the OPE error falls within the allowable range.

When the exposure is performed with the exposure apparatus 10 to which the management unit 18 applies the obtained exposure conditions (Step S107), the resist pattern can be formed with desired dimensional accuracy, and the semiconductor device including the desired dimensional circuit pattern can be produced.

In the first embodiment, the correction amount of the setting (such as the illumination shape and the lens aberration) of the exposure apparatus is computed until the desired accuracy of resist dimension is obtained with the small best focus difference. The inter-pattern best focus difference is suppressed by performing the exposure processing with the exposure apparatus having the setting to which the correction amount obtained by the above-described method is imparted, so that the accuracy of resist dimension can be improved to enhance the yield of the semiconductor device production.

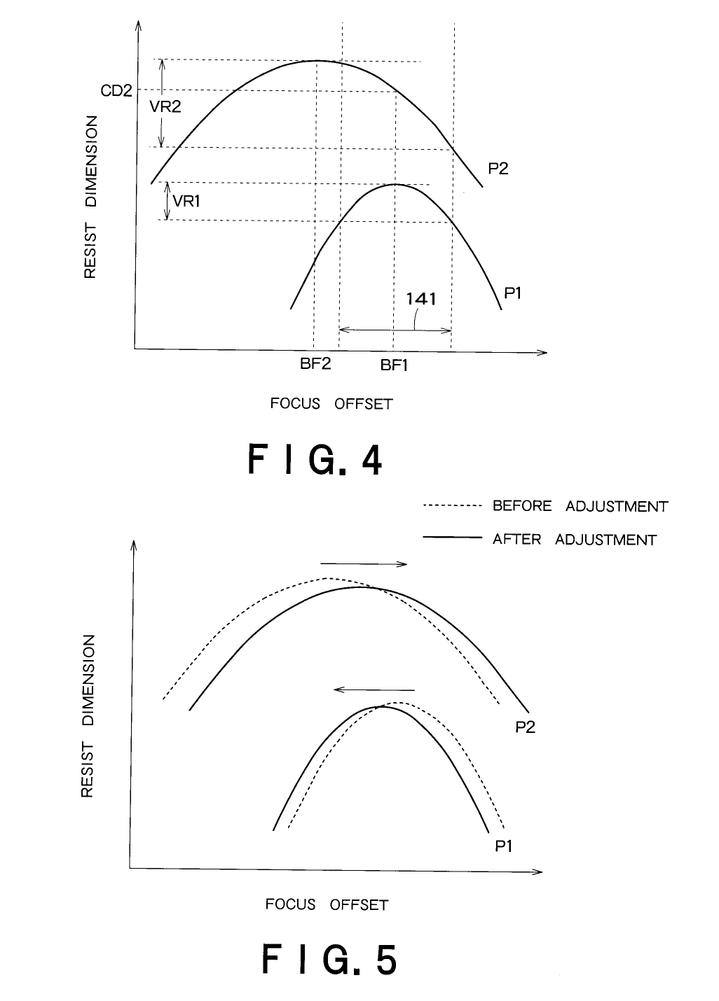

In Step S104 of the flowchart of FIG. 3, when the dimensional variation range of the transcriptional pattern exceeds an allowable value within the defined focus management range, the correction amount of the projection lens aberration that best focus difference may be computed such that the dimensional variation range becomes the allowable value or less. The description will be made with reference to FIGS. 4 to 6.

FIG. 4 is a graph illustrating an example of a relationship between the resist dimension and focus offsets (intentionally imparted focus errors) of patterns P1 and P2 having different shapes. A best focus BF1 of the pattern P1 is not matched with a best focus BF2 of the pattern P2. A focus management range 141 of 150 nm is defined around the best focus BF1 of the pattern P1 having large dimensional change sensitivity to the focus offset.

Then dimensional variation ranges VR1 and VR2 are obtained in the focus management range 141 of each of the patterns P1 and P2. At this point, it is assumed that the pattern P2 has the dimensional variation range VR2 of 10 nm exceeding the allowable value of 5 nm.

As illustrated in FIG. 5, spherical aberration of the projection lens is adjusted such that the best focus difference between the patterns P1 and P2 is reduced. At this point, the exposure amount is simultaneously adjusted such that the dimension of the pattern P1 at the best focus becomes the desired value.

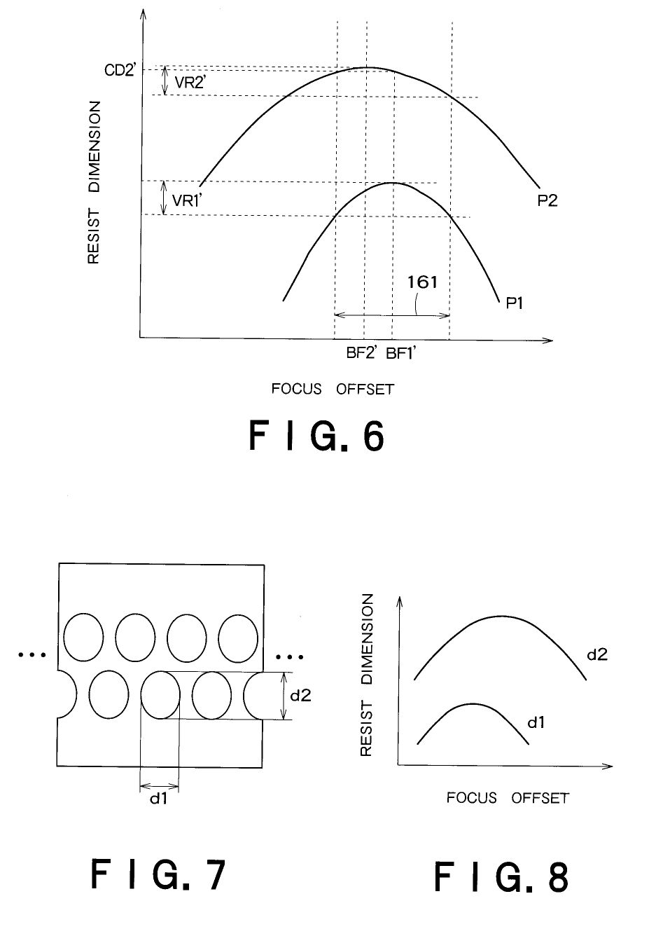

FIG. 6 illustrates a relationship between the focus offsets of the patterns P1 and P2 and the resist dimension after the lens aberration is adjusted. As with FIG. 4, a focus management range 161 is defined, and dimensional variation ranges VR1′ and VR2′ of the patterns P1 and P2 are obtained in the focus management range 161.

Although a best focus BF1′ of the pattern P1 is not completely matched with the best focus BF2′ of the pattern P2, the dimensional variation range VR2′ of 4 nm of the pattern P2 becomes smaller than the allowable of 5 nm, and it is determined that the desired projection lens aberration is adjusted.

As illustrated in FIG. 4, the dimension of the pattern P2 before the spherical aberration adjustment is a dimension CD2 located in the best focus BF1 of the pattern P1 that is of the reference pattern. On the other hand, as illustrated in FIG. 6, the dimension of the pattern P2 after the spherical aberration adjustment is a dimension CD2′ located in the best focus BF1′ of the pattern P1 that is of the reference pattern, and the dimension CD2′ is larger than the dimension CD2.

In Step S102 of the flowchart of FIG. 3, the correction amount such as the illumination shape is computed such that the OPE error is reduced to become the desired value. However, the OPE error possibly becomes larger than the OPE error considered in Step S102 by reducing the best focus difference (by adjusting the lens aberration) as illustrated in FIGS. 4 to 6. Accordingly, when the OPE error becomes larger than the allowable value, the procedure returns to Step S102 to re-compute the correction amount such as the illumination shape.

The correction amount such as the illumination shape that reduces the OPE error and the correction amount such as the lens aberration that reduces the best focus difference are repeatedly computed to obtain the exposure conditions that improve the accuracy of resist dimension.

The OPE error between at least the two kinds of patterns having different shapes are described in the first embodiment. Alternatively, the “two kinds” are set to different dimensional definition points in the same pattern. For example, when a short-diameter dimension d1 and a long-diameter dimension d2 of a transcriptional pattern of FIG. 7 are managed, occasionally the short-diameter dimension d1 differs from the long-diameter dimension d2 in the dimensional accuracy. Further, as illustrated in FIG. 8, the short-diameter dimension d1 differs from the long-diameter dimension d2 in the best focus. In such cases, as illustrated in FIG. 3, projection lens astigmatism can be adjusted to correct the best focus difference while the setting of the exposure apparatus is adjusted to obtain the desired dimensional accuracy.

In the first embodiment, after the exposure amount is determined such that the dimension of one reference pattern becomes the target value, OPE is adjusted such that the dimensional error of the other transcriptional pattern becomes small. Alternatively, the following method may be adopted.

First, plural reference patterns are defined, and the exposure amount is determined such that the amounts of deviation of the reference pattern dimensions from the target value (the sum of squares or a maximum value of the deviation) become the minimum. Then an OPE management pattern (group) is defined while including the plural reference patterns, and the exposure apparatus is adjusted such that the OPE error becomes the minimum.

An adequate value on another exposure apparatus is directly used to obtain OPE, and then the exposure apparatus may be adjusted such that the OPE error becomes the minimum.

### Second Embodiment

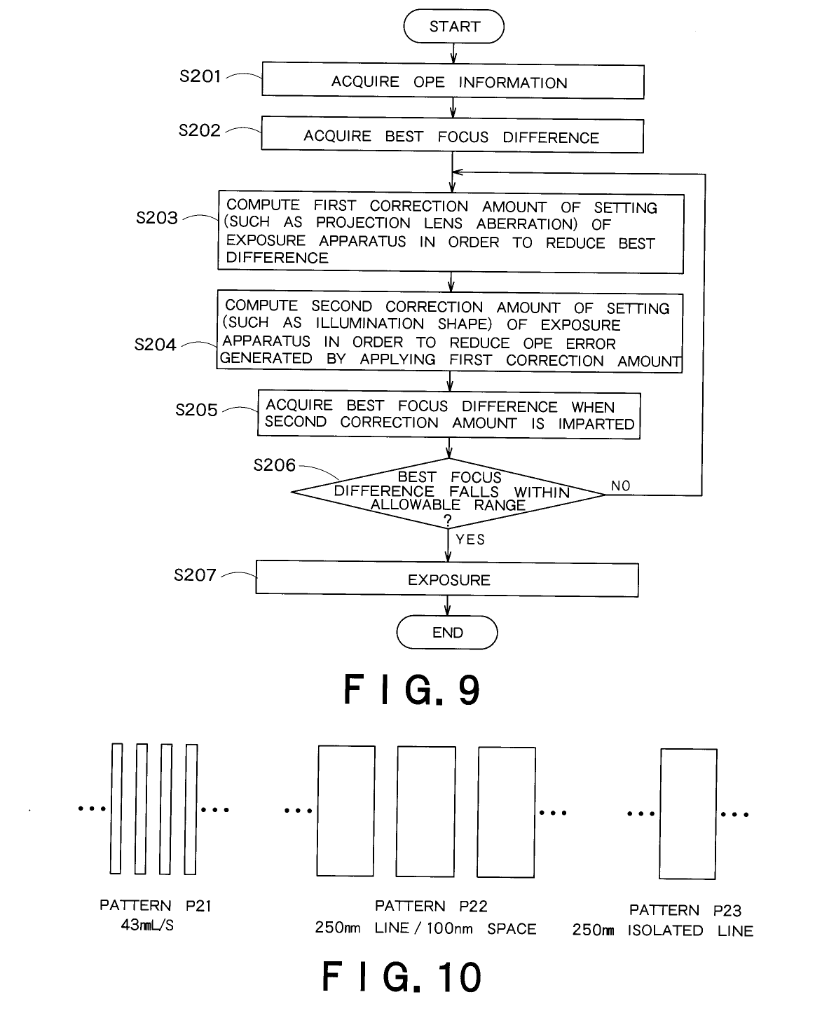

An exposure method according to a second embodiment of the invention will be described below with reference to a flowchart of FIG. 9. It is assumed that an exposure system of the second embodiment is similar to the exposure system of the first embodiment of FIG. 1. In the first embodiment, after the correction amount of the setting of the exposure apparatus 10 is computed to reduce the OPE error, the correction amount of the setting of the exposure apparatus 10 is computed to reduce the best focus difference. On the other hand, in the second embodiment, the sequence is reversed.

(Step S201) The computing unit 19 obtains pieces of OPE information on at least the two patterns when the transcriptional pattern formed in the mask 15 is collectively transcribed onto the substrate 16 under predetermined exposure conditions.

For example, three kinds of patterns P21, P22, and P23 are laid out in the mask 15 as illustrated in FIG. 10, and the resist pattern is collectively formed in the substrate by scan exposure. The exposure apparatus 10 is an immersion exposure apparatus having NA of 1.30, and quadrupole illumination is used in the exposure apparatus 10.

The pattern P21 is the finest pattern. In the pattern P21, on the illumination conditions used, the dimensional change has the largest influence on the error of the exposure amount while the depth of focus is extremely wide. The exposure amount is determined such that the pattern P21 becomes the desired dimension.

(Step S202) The inter-pattern best focus difference whose OPE information is obtained in Step S201 is computed. The method for computing the best focus difference is similar to that in Step S103.

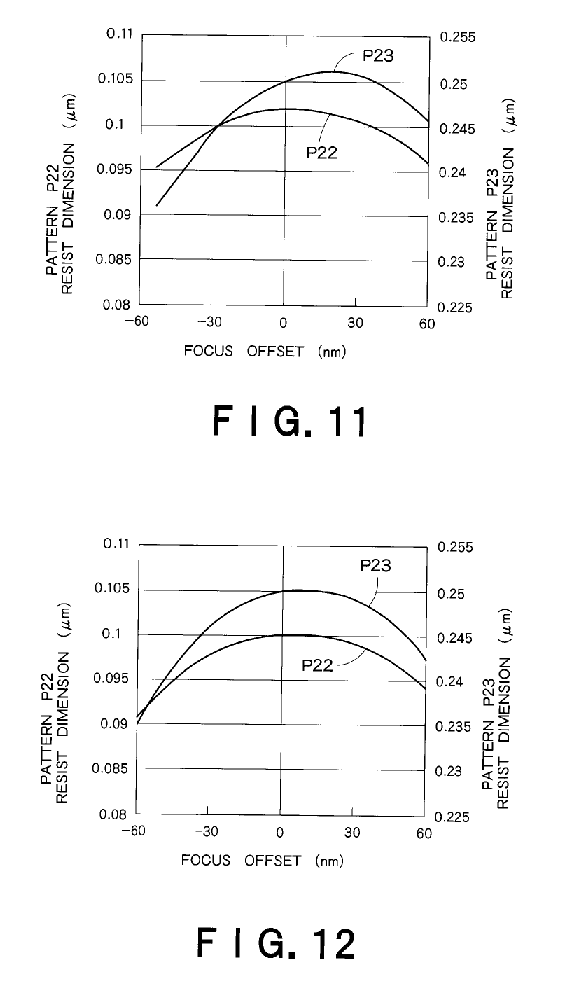

FIG. 11 illustrates a relationship between the focus offsets of the patterns P22 and P23 and the resist dimension. As can be seen from FIG. 11, the best focus difference of about 20 nm is generated between the patterns P22 and P23.

(Step S203) A first correction amount of the setting of the exposure apparatus 10 is computed such that the best focus difference obtained in Step S202 is reduced. For example, the setting of the exposure apparatus 10, which obtains the first correction amount, is the projection lens aberration.

As illustrated in FIG. 12, the inter-pattern best focus difference can be reduced by imparting spherical aberration (ninth term of Zernike aberration) of −20 mλ to the projection lens of the exposure apparatus 10.

(Step S204) A second correction amount of the setting of the exposure apparatus 10 is computed such that the OPE error generated by applying the first correction amount is reduced. Examples of the setting of the exposure apparatus 10, which obtains the second correction amount, include the illumination shape (illumination sigma value) in the illumination optical system 11 and NA of projection optical system 13.

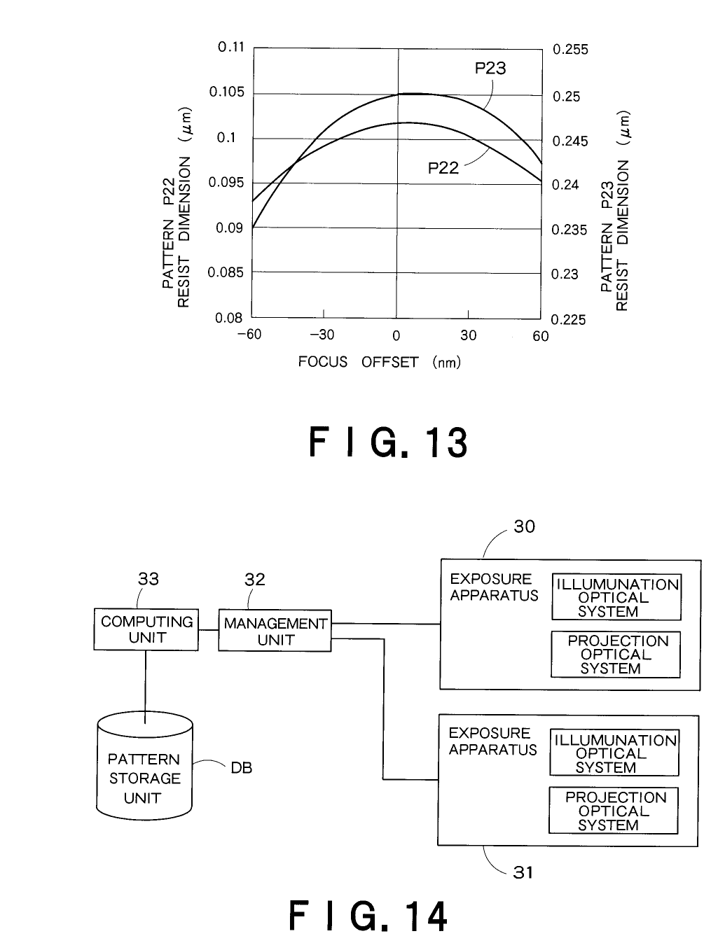

As can be seen from comparison of the graphs of FIGS. 11 and 12, the resist dimension is changed in the best focus position of the pattern P22 by reducing the best focus difference. Therefore, the illumination sigma value is adjusted so as to be decreased by 0.01. As illustrated in FIG. 13, the resist dimension at the focus offset of 0 of the pattern P22 becomes identical to the value of FIG. 11. The resist dimension of the pattern P21 is hardly changed. In the pattern P21, the depth of focus is wide, and the exposure amount is determined so as to become the desired dimension.

(Step S205) The best focus position is computed after the second correction amount is applied.

(Step S206) A determination whether the best focus difference computed in Step S205 falls within the allowable range is made. The procedure goes to Step S207 when the best focus difference falls within the allowable range. When the best focus difference does not fall within the allowable range, the procedure returns to Step S203 to adjust the projection lens aberration again.

In an example of FIG. 13, even if the illumination sigma value is adjusted, because the inter-pattern best focus difference is maintained, the processing is ended.

When the exposure is performed under the exposure conditions obtained as described above (Step S207), the resist pattern can be formed with desired dimensional accuracy, and the semiconductor device including the desired dimensional circuit pattern can be produced.

In the second embodiment, the correction amount of the setting (such as the lens aberration and the illumination sigma value) of the exposure apparatus is repeatedly computed until the desired accuracy of resist dimension is obtained with the small best focus difference. The exposure processing is performed with the exposure apparatus of the setting to which the correction amount obtained by the above-described method is imparted. Therefore, as with the first embodiment, the inter-pattern best focus difference is suppressed to improve the accuracy of resist dimension, which allows the enhancement of the yield of the semiconductor device production.

### Third Embodiment

An exposure system according to a third embodiment of the invention will be described with reference to FIG. 14. The exposure system includes an exposure apparatus 30, an exposure apparatus 31, a management unit 32, a computing unit 33, and a pattern storage unit DB. The exposure apparatuses 30 and 31 have the same configuration as the exposure apparatus 10 of the first embodiment. The exposure apparatuses 30 and 31 are the same model, and the mask in which the same pattern is formed is used in the exposure apparatuses 30 and 31. For example, the mask is subjected to OPC corresponding to the exposure apparatus 30.

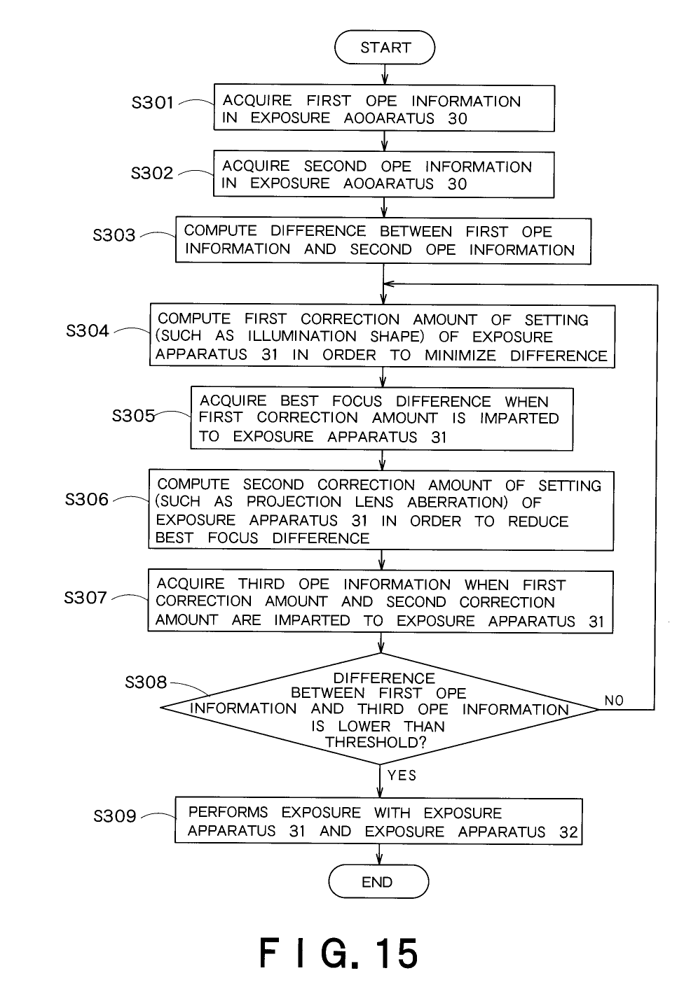

An exposure method in which the exposure system is used will be described with reference to a flowchart of FIG. 15.

(Step S301) The computing unit 33 obtains first OPE information when the transcriptional pattern formed in the mask with the exposure apparatus 30 is collectively transcribed onto the substrate. In the exposure apparatus 30, the apparatus setting may previously be adjusted such that the best focus difference between the transcriptional patterns formed in the mask falls within the allowable range.

(Step S302) The computing unit 33 obtains second OPE information when the transcriptional pattern formed in the mask with the exposure apparatus 31 is collectively transcribed onto the substrate.

(Step S303) The computing unit 33 computes a difference between the first OPE information and the second OPE information.

(Step S304) The computing unit 33 computes a first correction amount of the setting of the exposure apparatus 31 such the difference is minimized. Examples of the setting of the exposure apparatus 31, which obtains the first correction amount, include the illumination shape (illumination sigma value) in the illumination optical system and NA of the projection optical system.

(Step S305) The computing unit 33 computes the best focus difference that is generated by applying the first correction amount to the exposure apparatus 31.

(Step S306) The computing unit 33 computes the second correction amount of the setting of the exposure apparatus 31 such that the best focus difference obtained in Step S305 falls within the allowable range. For example, the setting of the exposure apparatus 31, which obtains the second correction amount, is the projection lens aberration.

(Step S307) The computing unit 33 obtains third OPE information when the transcriptional pattern formed in the mask with the exposure apparatus 31 is collectively transcribed onto the substrate under the exposure conditions to which the first correction amount and the second correction amount are imparted.

(Step S308) The computing unit 33 computes a difference between the first OPE information and the third OPE information, and determines whether the difference is equal to or lower than a predetermined threshold. The procedure goes to Step S309 when the difference is equal to or lower than the threshold, and the procedure returns to Step S304 when the difference is more than the threshold.

In Step S307, the difference (OPE error) is possibly not lower than the threshold, because the correction amount such as the projection lens aberration is imparted in order to reduce the best focus difference while the correction amount such as the illumination shape is imparted in order to minimize the difference. Therefore, the pieces of processing in Steps S304 to S308 are repeated until the difference becomes the threshold or less.

(Step S309) The exposure apparatus 30 and the exposure apparatus 31 perform the exposure processing. The management unit 32 applies the first correction amount and the second correction amount to the exposure apparatus 31.

The difference between the OPE information on the exposure apparatus 30 and the OPE information on the exposure apparatus 31 is decreased by the method, and the mask in which the same pattern is formed can be used in both of the exposure apparatuses. It is not necessary to prepare the mask to which OPC is performed every exposure apparatus, so that the cost of the semiconductor device production can be reduced.

The inter-pattern best focus difference is suppressed to improve the accuracy of resist dimension, which allows the enhancement of the yield of the semiconductor device production.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An exposure method comprising:
acquiring first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus;
computing a first OPE error based on the first OPE information;
computing a first correction amount of an exposure condition, the first correction amount reducing the first OPE error;
computing a best focus difference between the first transcriptional pattern portion and the second transcriptional pattern portion, the first transcriptional pattern portion and the second transcriptional pattern portion being transcribed with the exposure apparatus to which the first correction amount is imparted;
computing a second correction amount of a projection optical system of the exposure apparatus, the second correction amount reducing the best focus difference;
acquiring second OPE information corresponding to the first transcriptional pattern portion and the second transcriptional pattern portion, the first transcriptional pattern portion and the second transcriptional pattern portion being transcribed with the exposure apparatus to which the first correction amount and the second correction amount are imparted;
computing a second OPE error based on the second OPE information; and
performing exposure processing with the exposure apparatus using a mask comprising the mask pattern, the first correction amount and the second correction amount being imparted to the exposure apparatus, when the second OPE error is included in a predetermined range.

2. The exposure method according to claim 1, wherein the first correction amount, the best focus difference, and the second correction amount are repeatedly computed until the second OPE error is included in the predetermined range.

3. The exposure method according to claim 1, wherein the first correction amount of the exposure condition includes a correction amount concerning at least one of an illumination shape, NA of the projection optical system, a scan surface inclined amount of a wafer stage, a scan surface inclined amount of a mask stage, a spectral shape of a wavelength of exposure light, and a polarization degree of exposure light.

4. The exposure method according to claim 1, wherein the second correction amount of the projection optical system includes a correction amount concerning projection lens aberration.

5. The exposure method according to claim 1, wherein the first pattern portion and the second pattern portion are different dimensional definition points in an identical pattern.

6. The exposure method according to claim 1, comprising:
acquiring third OPE (Optical Proximity Effect) information corresponding to a third transcriptional pattern portion and a fourth transcriptional pattern portion, the third transcriptional pattern portion and the fourth transcriptional pattern portion being formed by transcribing the first pattern portion and the second pattern portion onto the substrate with a second exposure apparatus;
computing a difference between the first OPE information and the third OPE information as the first OPE error;
computing a difference between the second OPE information and the third OPE information as the second OPE error; and
performing exposure processing with the exposure apparatus and the second exposure apparatus using a mask comprising the mask pattern, the first correction amount and the second correction amount being imparted to the exposure apparatus, when the second OPE error is included in a predetermined range.

7. An exposure method comprising:
acquiring first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus;
computing a first best focus difference between the first transcriptional pattern portion and the second transcriptional pattern portion with the exposure apparatus;
computing a first correction amount of a projection optical system of the exposure apparatus, the first correction amount reducing the first best focus difference;
acquiring second OPE information corresponding to the first transcriptional pattern portion and the second transcriptional pattern portion, the first transcriptional pattern portion and the second transcriptional pattern portion being transcribed with the exposure apparatus to which the first correction amount are imparted;
computing an OPE error based on the second OPE information;
computing a second correction amount of an exposure condition, the second correction amount reducing the OPE error;
computing a second best focus difference between the first transcriptional pattern portion and the second transcriptional pattern portion, the first transcriptional pattern portion and the second transcriptional pattern portion being transcribed with the exposure apparatus to which the first correction amount and the second correction amount are imparted; and
performing exposure processing with the exposure apparatus using a mask comprising the mask pattern, the first correction amount and the second correction amount being imparted to the exposure apparatus, when the second best focus difference is included in a predetermined range.

8. The exposure method according to claim 7, wherein the first correction amount, the OPE error, and the second correction amount are repeatedly computed until the second best focus difference is included in the predetermined range.

9. The exposure method according to claim 7, wherein the first correction amount of the projection optical system includes a correction amount concerning projection lens aberration.

10. The exposure method according to claim 7, wherein the second correction amount of the exposure condition includes a correction amount concerning at least one of an illumination shape, NA of the projection optical system, a scan surface inclined amount of a wafer stage, a scan surface inclined amount of a mask stage, a spectral shape of a wavelength of exposure light, and a polarization degree of exposure light.

11. The exposure method according to claim 7, wherein the first pattern portion and the second pattern portion are different dimensional definition points in an identical pattern.

12. An exposure system comprising:
an exposure apparatus which comprises a projection optical system;
a computing unit which
acquires first OPE (Optical Proximity Effect) information corresponding to a first transcriptional pattern portion and a second transcriptional pattern portion, the first transcriptional pattern portion and the second transcriptional pattern portion being formed by transcribing a first pattern portion and a second pattern portion of a mask pattern onto a substrate with an exposure apparatus,
computes a first OPE error based on the first OPE information,
computes a first correction amount of an exposure condition, the first correction amount reducing the first OPE error,
computes a best focus difference between the first transcriptional pattern portion and the second transcriptional pattern portion, the first transcriptional pattern portion and the second transcriptional pattern portion being transcribed with the exposure apparatus to which the first correction amount is imparted,
computes a second correction amount of a projection optical system of the exposure apparatus, the second correction amount reducing the best focus difference,
acquires second OPE information corresponding to the first transcriptional pattern portion and the second transcriptional pattern portion, the first transcriptional pattern portion and the second transcriptional pattern portion being transcribed with the exposure apparatus to which the first correction amount and the second correction amount are imparted, and computes a second OPE error based on the second OPE information; and
a management unit that imparts the first correction amount and the second correction amount to the exposure apparatus when the second OPE error is included in a predetermined range.

13. The exposure system according to claim 12, wherein the first correction amount of the exposure condition includes a correction amount concerning at least one of an illumination shape, NA of the projection optical system, a scan surface inclined amount of a wafer stage, a scan surface inclined amount of a mask stage, a spectral shape of a wavelength of exposure light, and a polarization degree of exposure light.

14. The exposure system according to claim 12, wherein the second correction amount of the projection optical system includes a correction amount concerning projection lens aberration.
